(19) United States
(12) Patent Application Publication
(10) Pub. No.: US 2016/0013275 A1
(43) Pub. Date: Jan. 14, 2016

(54) III-NITRIDE SEMICONDUCTOR STACKED STRUCTURE

(71) Applicant: SOFT-EPI INC., Yongin-si Gyeonggi-do (KR)

(72) Inventors: Sung Min HWANG, Gyeonggi-do (KR); Doo Soo KIM, Gyeonggi-do (KR)

(73) Assignee: Soft-Epi Inc., Gyeonggi-do (KR)

(21) Appl. No.: 14/648,021

(22) PCT Filed: Nov. 29, 2013
(86) PCT No.: PCT/KR2013/011014

§ 371 Date: Sep. 14, 2015

(30) Foreign Application Priority Data
Nov. 30, 2012 (KR) 10-2012-0137860
Apr. 10, 2013 (KR) 10-2013-0039355

(51) Int. Cl. H01L 29/20; H01L 29/06; H01L 29/04

(52) U.S. Cl. CPC H01L 29/2003; H01L 29/045; H01L 29/0657

(57) ABSTRACT

The disclosure relates to an m-plane substrate, a growth inhibitor region located on the m-plane substrate, the growth inhibitor region having a plurality of windows for growing a III-nitride semiconductor, a seed layer formed at least at regions corresponding to the plurality of windows on the m-plane substrate, and a III-nitride semiconductor layer grown from the seed layer and coalesced after propagated along a-axis and c-axis directions.

### FIELD

The present disclosure relates generally to a III-nitride semiconductor stacked structure, and more particularly, to a III-nitride semiconductor stacked structure having a cavity.

Within the context herein, the expression “III-nitride semiconductor” is intended to indicate a compound semiconductor layer composed of Al₍ₓ₎Ga_{(y)}In_{(1-x-y)}N (wherein, 0≦x≦1, 0≦y≦1, 0≦x+y≦1), which can be used in a wide variety of applications, e.g., in the manufacture of optical elements including light emitting devices such as light emitting diodes and light receiving devices such as photodiodes, and in the manufacture of diodes, transistors, electrical devices and so forth.

### BACKGROUND

This section provides background information related to the present disclosure which is not necessarily prior art.

FIG. 1 is a diagrammatic view illustrating an example of III-nitride semiconductor light emitting devices described in U.S. Patent Application Publication 2003-0057444, in which the III-nitride semiconductor light emitting device includes a substrate 100, an n-type III-nitride semiconductor layer 300 growing on the substrate 100, an active layer 400 growing on the n-type III-nitride semiconductor layer 300, and a p-type III-nitride semiconductor layer 500 growing on the active layer 400. Protrusions 110 are formed on the substrate 100 where the protrusions 110 improve the growth quality of the III-nitride semiconductor layers 300, 400, 500 that grow on the substrate 100, and they also serve as a scattering surface for increasing the efficiency of extracting light generated by the active layer 400 out of the light emitting device.

FIG. 2 and FIG. 3 are diagrammatic views illustrating an example of the III-nitride semiconductor light emitting device described in WO Patent [Application] Publication 2010-110608, in which the III-nitride semiconductor light emitting device includes a substrate 100, an active layer 400 growing on the n-type III-nitride semiconductor layer 300, and a p-type III-nitride semiconductor layer 500 growing on the active layer 400. Protrusions 120 are formed on the substrate 100, and the III-nitride semiconductor layers 300, 400, 500 are grown on the top face of the protrusions 120, so as to form cavities 130. The use of cavities 130 (the refractive index of air is 1) is incorporated to increase the scattering effect as compared to using a scattering surface between the III-nitride semiconductor layers 300, 400, 500 and the substrate 100 (in case of a sapphire substrate, its refractive index is approximately 1.7). Referring back to FIG. 3, however, the III-nitride semiconductor layers 300, 400, 500 that were actually grown on the protrusions 130 merely formed a scattering surface 131 having a very low curvature, contrary to expectations. Meanwhile, those cavities 130 thus formed are used not only as a scattering surface, they are also used as a channel where an etchant is introduced when the substrate 100 and the III-nitride semiconductor layers 300, 400, 500 are separated by wet etching, or as a passage for gas generated during a laser lift-off process and for reducing laser lift-off surfaces during the laser lift-off process such that an impact upon the III-nitride semiconductor layers 300, 400, 500 can be mitigated.

FIG. 4 is a diagrammatic view illustrating an example of the III-nitride semiconductor stack described in US Patent Application Publication 2005-0156175, in which the III-nitride semiconductor stack includes a c-plane sapphire substrate 100, a III-nitride semiconductor template 210 preformed on the c-plane sapphire substrate 100, a growth inhibitor film 150 composed of SiO₂ to be formed on the III-nitride semiconductor template 210, and a III-nitride semiconductor layer 310 selectively grown thereon. The III-nitride semiconductor template 210 is formed by a conventional method of growing a III-nitride semiconductor on the c-plane sapphire substrate 100. That is, a seed layer is formed at a growth temperature around 550° C. under hydrogen atmosphere, and then GaN is grown to a thickness of 1 to 3 μm at a growth temperature of 1050° C. Reference numeral 180 illustrates detects. Overall improvements in the crystallinity are brought by stopping the propagation of defects under the growth inhibitor film 150. However, this method requires that the III-nitride semiconductor template 210 grows prior to the formation of the growth inhibitor film 150, and differences in the lattice constants and coefficients of thermal expansion between the III-nitride semiconductor template 210 and the c-plane sapphire substrate 100 result in bowing of the substrate. This bowing of the substrate interferes with a subsequent photolithography process required for forming the growth inhibitor film 150 such that it may become difficult to carry out the process equally on the c-plane sapphire substrate 100 typically having a diameter of 2, 4, 6 or 8 inches. An attempt has been made using an m-plane substrate, as described in P. de Mierry et al., Improved semipolar (11-22) GaN quality using asymmetric lateral epitaxy, Applied Physics Letters 94, 191903 (2009).

FIG. 5 is a diagrammatic view illustrating another example of the III-nitride semiconductor stack described in US Patent Application Publication 2005-0156175, in which the III-nitride semiconductor stack includes a c-plane sapphire substrate 100, a growth inhibitor film 150 composed of SiO₂ to be formed on the c-plane sapphire substrate 100, and a III-nitride semiconductor layer 310 selectively grown thereon. As the III-nitride semiconductor layer 310 growing at approximately 1050° C. cannot be grown on the c-plane 100 and the growth inhibitor film 150, a seed layer 200 (typically referred to as a buffer layer) first needs to be formed at a growth temperature of 550° C., as in case of the III-nitride semiconductor template 210 of FIG. 4. However, when the seed layer 200 is formed at a temperature much lower than the actual growth temperature of the III-nitride semiconductor (e.g. the growth temperature of GaN is typically 1000° C. or higher), polycrystals of a material (usually, GaN) for the seed layer 200 is formed even on the growth inhibitor film 150, making it hard to obtain a III-nitride semiconductor layer 310 with excellent crystallinity.

### TECHNICAL PROBLEM

The problems to be solved by the present disclosure will be described in the latter part of the best mode for carrying out the invention.

### TECHNICAL SOLUTION

This section provides a general summary of the disclosure and is not a comprehensive disclosure of its full scope or all of its features.

According to an aspect of the present disclosure, there is provided a III-nitride semiconductor stacked structure comprising: an m-plane substrate; a growth inhibitor region located on the m-plane substrate, the growth inhibitor region having a plurality of windows for growing a III-nitride semiconductor; a seed layer formed at least at regions corresponding to the plurality of windows on the m-plane substrate; and a III-nitride semiconductor layer grown from the seed layer and coalesced after propagated along a-axis and c-axis directions, in which a III-nitride semiconductor propagated along the c-axis direction from one window and then propagated above the growth inhibitor region forms a cavity with a III-nitride semiconductor propagated along the a-axis direction from a neighboring window.

### Advantageous Effects

The advantageous effects of the present disclosure will be described in the latter part of the best mode for carrying out the invention.

### DESCRIPTION OF DRAWINGS

FIG. 1 is a diagrammatic view illustrating an example of III-nitride semiconductor light emitting devices described in U.S. Patent Application Publication 2003-0057444.

FIG. 2 and FIG. 3 are diagrammatic views illustrating an example of the III-nitride semiconductor light emitting device described in WO Patent Application Publication 2010-110608.

FIG. 4 is a diagrammatic view illustrating an example of the III-nitride semiconductor stack described in US Patent Application Publication 2005-0156175.

FIG. 5 is a diagrammatic view illustrating another example of the III-nitride semiconductor stack described in US Patent Application Publication 2005-0156175.

FIG. 6 is a diagrammatic view illustrating an example of a III-nitride semiconductor stacked structure according to the present disclosure.

FIG. 7 is a diagrammatic view illustrating an example of a method of growing III-nitride semiconductors on a seed layer according to the present disclosure.

FIG. 8 is a diagrammatic view illustrating another example of a method of growing III-nitride semiconductors on a seed layer according to the present disclosure.

FIG. 9 is a diagrammatic view illustrating another example of a III-nitride semiconductor stacked structure according to the present disclosure.

FIG. 10 is a diagrammatic view illustrating yet another example of a III-nitride semiconductor stacked structure according to the present disclosure.

FIG. 11 is a diagrammatic view illustrating yet another example of a III-nitride semiconductor stacked structure according to the present disclosure.

FIG. 12 shows sectional images of the III-nitride semiconductor stacked structure of FIG. 6, which has grown in the structure illustrated in FIG. 8.

FIG. 13 shows sectional images of the III-nitride semiconductor stacked structure of FIG. 6, which has grown in the structure illustrated in FIG. 8.

FIG. 14 shows photos of seed layers grown at a low temperature, and under hydrogen atmosphere, respectively.

FIG. 15 shows photos of a seed layer grown according to the present disclosure.

FIG. 16 and FIG. 17 are diagrammatic views describing an example of a method of growing a III-nitride semiconductor according to the present disclosure.

### DETAILED DESCRIPTION

Hereinafter, the present disclosure will now be described in detail with reference to the accompanying drawings.

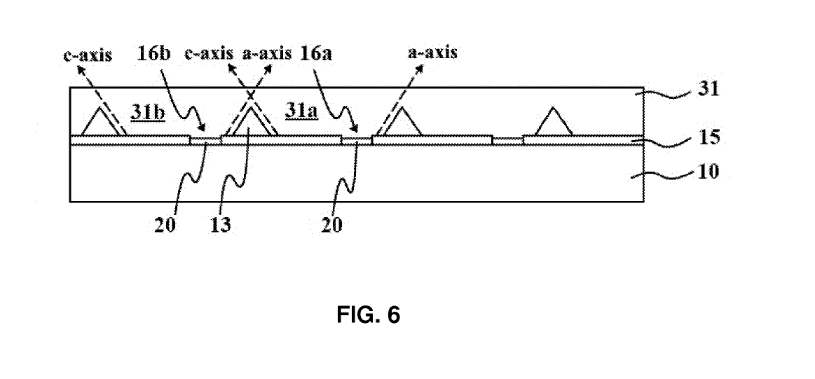

FIG. 6 is a diagrammatic view illustrating an example of a III-nitride semiconductor stacked structure according to the present disclosure, in which the III-nitride semiconductor stacked structure includes an m-plane substrate 10, a growth inhibitor film having a plurality of windows 16a, 16b for growing a III-nitride semiconductor, a seed layer formed at regions corresponding to the plurality of windows 16a, 16b on the m-plane substrate 10 in the region, a III-nitride semiconductor layer 31 grown from the seed layer 20 and coalesced after propagated along a-axis and c-axis directions, in which a III-nitride semiconductor 31a propagated along the c-axis direction from one window 16a and then propagated above the growth inhibitor film 15 forms a cavity 13 with a III-nitride semiconductor 31b propagated along the a-axis direction from a neighboring window 16b.

A typical material for the m-plane substrate 10 is hexagonal sapphire, in which the m-plane is (1-100) and the a-plane is (11-20), with respect to the c-plane (0001). Here, the a-axis is defined as an axis normal to the a-plane, and the c-axis is defined as an axis normal to the c-plane. While it is preferred to use an accurate m-plane substrate 10, any substrate that is cut at a slight angle from the m-plane may also be used. These substrates are collectively called the m-plate substrate 10 in the description. Besides sapphire, any material that enables the growth of III-nitride semiconductors (e.g. GaN, InGaN, AlGaN, InN, AlN, InGaAlN) and has an m-plane may be used. The III-nitride semiconductor can be doped with a material such as Si or Mg.

The growth inhibitor film 15 is usually made of SiO₂. It can also be made of SiNₓ or TiO₂ or any material that prevents the growth of III-nitride semiconductors. In addition, the growth inhibitor film 15 can be formed into a SiO₂/TiO₂ DBR structure. For instance, a SiO₂ film having a thickness of 100 to 300 nm can be used. Moreover, the growth inhibitor film 15 can be formed into stripes along the a-plane direction of the m-plane sapphire substrate, and a width ratio between the growth inhibitor film 15 and the window 16a can be suitably adjusted. The inventors have conducted experiments on a width ratio between the growth inhibitor film 15 and the window 16a, using 17:1, 16:2, 13:1, 14:2, 7:3, 6:2 masks (unit: μm) and found that the III-nitride semiconductor layer 31 (GaN) could be planarized to 7 μm or less (i.e. the height of the cavity 13 becomes 7 μm or less) even when the growth inhibitor film 15 has a maximum width of 17 μm. Therefore, according to the method of growing a III-nitride semiconductor according to the present disclosure, it is possible to planarize the III-nitride semiconductor layer 31 before reaching an excessive height (e.g. 10 μm).

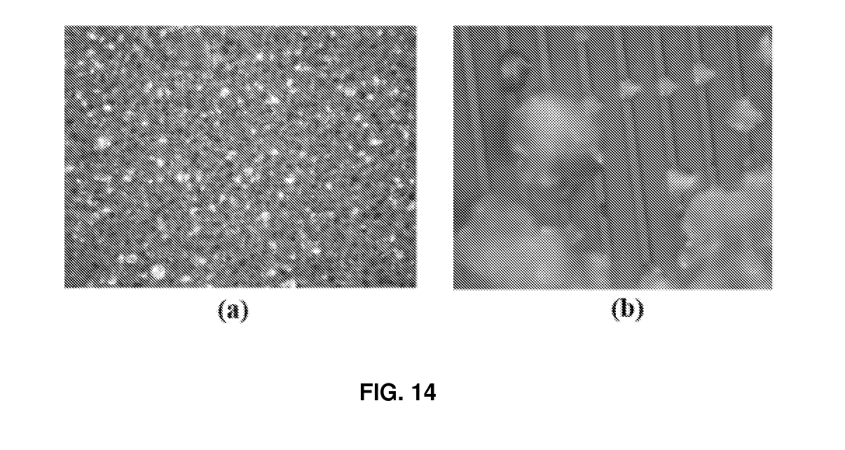

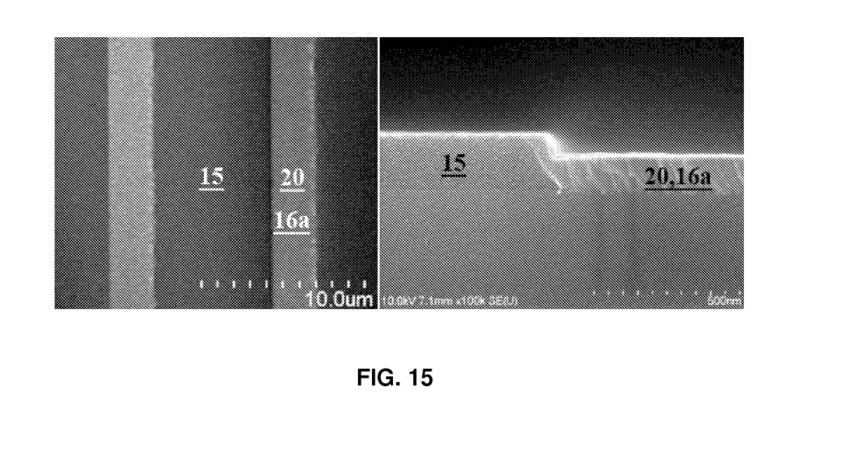

Unlike a GaN buffer layer that is typically formed at approximately 500° C. (e.g. 550° C.), the seed layer 20 (e.g. GaN) is formed at a high temperature not lower than 650° C., preferably not lower than 800° C., yet it may not be properly formed at a temperature of 1150° C. or higher. Although it is possible to form a superior seed layer 20 at a temperature of 800° C. or higher, the seed layer can grow at a temperature of 900° C. or higher, for quick shifting to the growth conditions for the III-nitride semiconductor layer 31 growing at a higher temperature. From this point of view, the seed layer is preferably grown at a temperature not lower than 900° C. Furthermore, N₂ is used as a carrier gas in place of conventionally used H₂. As indicated above, a conventional method for growing a buffer layer results in the formation of polycrystals over the growth inhibitor film 15, making it difficult to obtain a III-nitride semiconductor layer 31 having good crystallinity. As such, it will be understood that the seed layer 20 according to this embodiment is different from a conventional buffer layer used for growing III-nitride semiconductor layers, in terms of its formation. FIG. 14 shows photos of seed layers grown at a low temperature, and under hydrogen atmosphere, respectively. As can be seen in (a), when a seed layer is grown at a low temperature, polycrystals cover up to the growth inhibitor film. As can be seen in (b), when a seed layer is grown under hydrogen atmosphere, the seed layer might not grow well, and rather very large nuclei may be formed in some parts. FIG. 15 shows photos of a seed layer grown according to the present disclosure. As can be seen in the figure, a seed layer 20 is formed at the window 16a only. Since the seed layer 20 grows in a narrow window 16a region, those growth conditions free of a growth inhibitor film 15 may cause the seed layer 20 to form at the window 16a too quickly, so that it is necessary to modify the growth rate based on the size of the window 16a. The seed layer 20 is composed of a compound semiconductor Al(x)Ga(y)In(1-x-y)N(0≦x≦1, 0≦y≦1, 0≦x+y≦1), preferably GaN. The seed layer 20 in FIG. 15 is grown in following growth condition. An m-plane sapphire undergoes cleansing, SiO₂ is deposited by PECVD thereon, and then a seed layer is grown by MOCVD. For an MOCVD reactor, N₂ is employed as an atmosphere gas, and NH₃ is introduced into the reactor at a designated flow rate of 8000 sccm (Standard Cubic Cm per Min.), starting from 450° C. up to 1050° C. This is done for nitridation treatment of the sapphire surface. At 1050° C., GaN nuclei were grown at a rate of 0.5 nm/sec using TMGa. Here, the pressure in the reactor was set to 100 mbar.

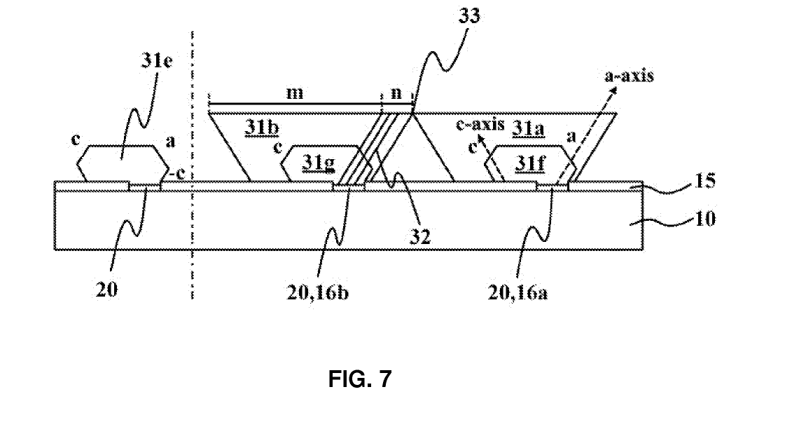

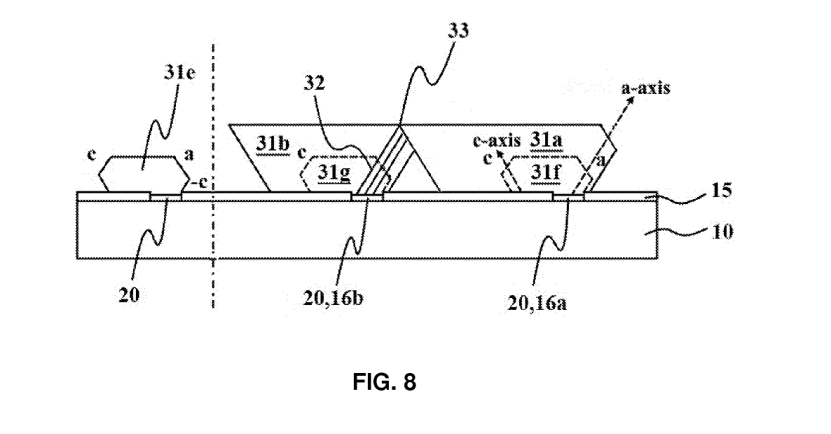

FIG. 7 is a diagrammatic view illustrating an example of a method of growing III-nitride semiconductors on a seed layer according to the present disclosure. In particular, an example of the process for coalescing a III-nitride semiconductor 31a and a III-nitride semiconductor 31b is described. As can be seen from the left side of FIG. 7, a III-nitride semiconductor 31e on a seed layer 20 of an m-plate substrate 10 can be grown with a c-plane, an a-plane and a -c-plane in the clockwise direction. Depending on the growth conditions, a certain plane may be broader or a certain plane may be omitted, basically the lateral propagation along the a-axis direction is suppressed relative to the lateral propagation along the c-axis direction. In addition, as can be seen from the middle in FIG. 7, crystal defects 32 (more precisely, stacking faults) are propagated along the a-axis direction. Therefore, a region n having crystal defects is made relatively narrower than a region m without crystal defects 32 when the III-nitride semiconductor 31a grown at the window 16a and the III-nitride semiconductor 31b grown at the neighboring window 16b reach a coalescence point 33, the region n is formed as it is propagated or grown along the a-axis direction and the region m is formed as it is propagated or grown along the c-axis direction, such that crystal defects across the III-nitride semiconductors 31a, 31b may be reduced. For proper coalescence, the a-planes of the III-nitride semiconductors 31a, 31b propagated along the a-axis direction are gradually reduced, optimally creating a point coalescence. Also, coalescence or planarization of the IIII-nitride semiconductor 31b propagated along the a-axis direction and the III-nitride semiconductor 31a propagated along the c-axis direction is assisted by reducing the c-plane of the III-nitride semiconductor 31a propagated along the c-axis direction, optimally creating a point coalescence or junction, up to the coalescence point 33. When the -c-plane of the III-nitride semiconductor 31b and the c-plane of the III-nitride semiconductor 31a meet at the coalescence point 33, they may not be coalesced easily, or they may grow in parallel without being coalesced. Preferably, those III-nitride semiconductors 31a, 31b grow after sub III-nitride semiconductor bulks 31f, 31g grown and propagated over a growth inhibitor region as the lateral growth-propagation rate of the III-nitride semiconductor propagated or grown along the c-axis direction is faster than that of the III-nitride semiconductor propagated along the a-axis direction, and/or sub III-nitride semiconductor bulks 31f, 31g having both a-plane and c-plane still existent are formed first. Because the height of a Ill-nitride semiconductor can be increased towards the coalescence point 33 in case of forming a III-nitride semiconductor of reversed trapezoidal shape from the early stage of the growth process, it is desirable to make the sub III-nitride semiconductor bulks 31f, 31g propagated over the growth inhibitor film 15 in advance. Moreover, since it is not necessarily easy to incorporate the III-nitride semiconductors 31a, 31b in reversed trapezoidal shape, it is desirable to prepare the sub III-nitride semiconductor bulks 31f, 31g in advance, as preforms for making such a shape. As described above, according to the method of growing a III-nitride semiconductor of the present disclosure, the Ill-nitride semiconductor layer 31 can still be coalesced at a thickness of 7 μm or less even when the ratio of widths of the growth inhibitor film 15 to the window 16a is 17:1, in which the sub III-nitride semiconductor bulks 31f, 31g are one of useful means for accomplishing it. After the seed layer 20 is grown, the atmosphere gas is changed to hydrogen. Then the sub III-nitride semiconductor bulks 31f, 31g are grown to a thickness range between 500 and 1300 nm, under 4000 sccm of NH₃, at the pressure of 100 mbar, the temperature of 1050° C., and the growth rate of 0.6 nm/sec. The growth process is continued, after lowering the temperature to 920° C. and setting the pressure to 250 mbar and NH₃ to 12,000 sccm. For instance, a structure as shown in FIG. 7 can be obtained by growing the sub III-nitride semiconductor bulks 31f, 31g to a thickness of 500 nm, and the region n can be reduced merely to 5% of the whole surface, thereby significantly reducing crystal defects 32. In addition, a structure as shown in FIG. 8 can be obtained by growing the sub III-nitride semiconductor bulks 31f, 31g to a thickness of 1300 nm, and crystal defects 32 may be blocked such that they would not break through the surface. Comparing the growth conditions of two layers, once the sub III-nitride semiconductor bulks 31f, 31g are grown at a relatively low pressure and a relatively high temperature, the III-nitride semiconductors 31a, 31b grown from the sub III-nitride semiconductor bulks 31f, 31g become relatively less sensitive to temperatures in their growth.

FIG. 8 is a diagrammatic view illustrating another example of a method of growing III-nitride semiconductors on a seed layer according to the present disclosure. In particular, another example of the coalescence process for a III-nitride semiconductor 31a and a III-nitride semiconductor 31b is described. Crystal defects 32 of the III-nitride semiconductor 31b propagated along the a-axis direction are blocked by the III-nitride semiconductor 31a. Likewise, propagation of the crystal defects 32 is blocked by reducing the c-plane of the III-nitride semiconductor 31a propagated along the c-axis direction up to a coalescence point 33 where the junction is completed, optimally creating a point coalescence, and thus assisting coalescence or planarization of the III-nitride semiconductor 31b propagated along the a-axis direction and of the III-nitride semiconductor 31a propagated along the c-axis direction.

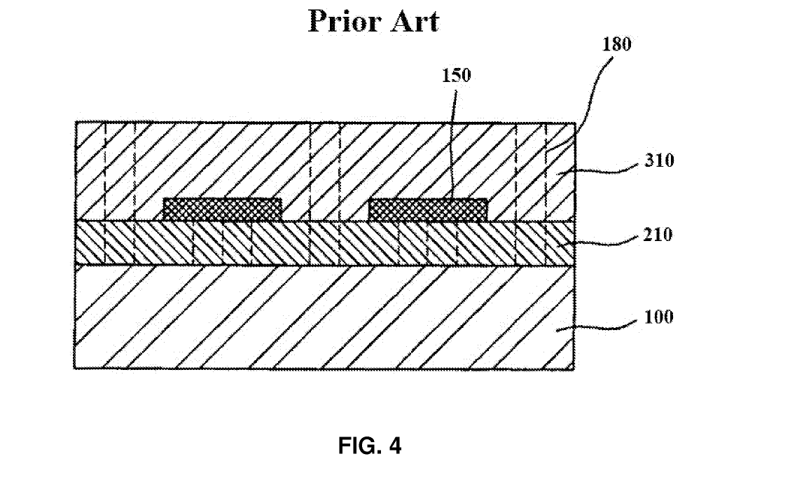

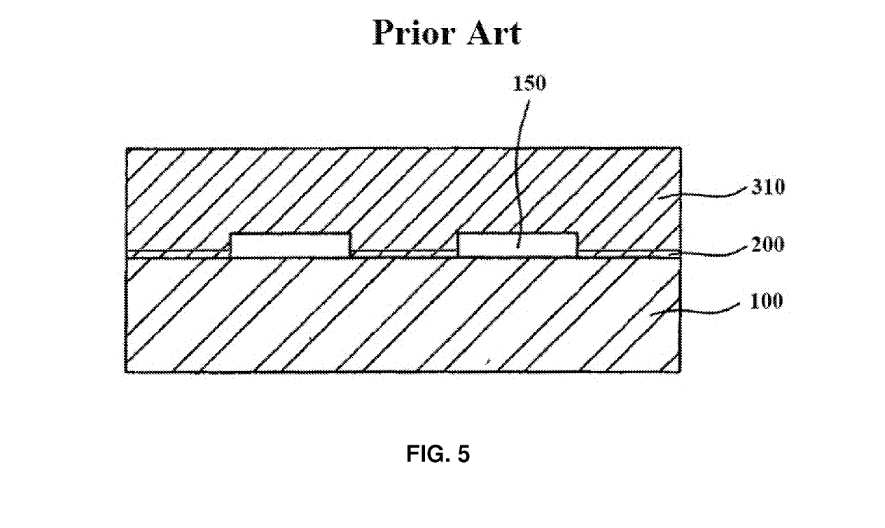

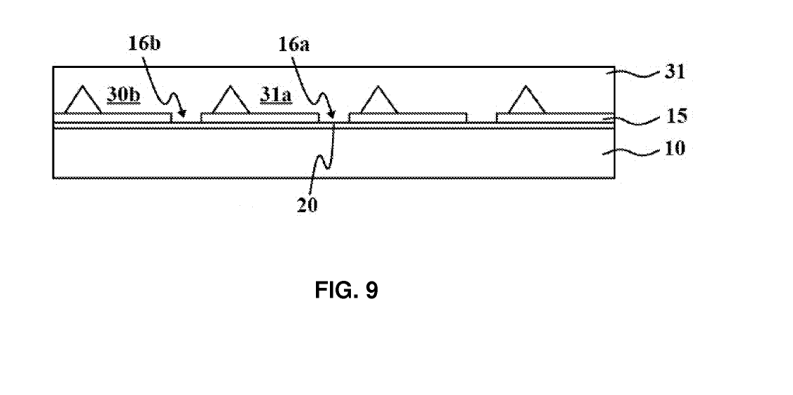

FIG. 9 is a diagrammatic view illustrating another example of a III-nitride semiconductor stacked structure according to the present disclosure, in which the III-nitride semiconductor stacked structure has a seed layer 20 disposed between a growth inhibitor film 15 and an m-plane substrate 10, as compared with the III-nitride semiconductor stacked structure of FIG. 6. That is, the seed layer 20 is formed prior to the formation of the growth inhibitor film 15. Those problems noted in connection with FIG. 4 may occur if a semiconductor layer is formed first, but they can be resolved by limiting the height of the seed layer 20. In case of this embodiment, the seed layer 20 may be formed of a conventional buffer layer.

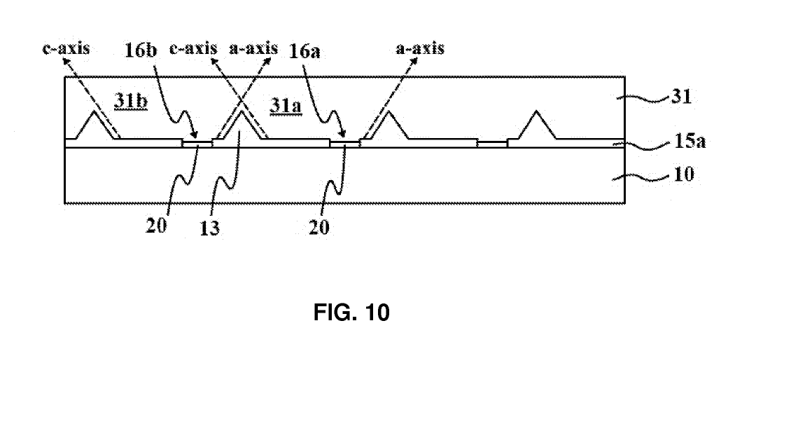

FIG. 10 is a diagrammatic view illustrating yet another example of a III-nitride semiconductor stacked structure according to the present disclosure, in which the III-nitride semiconductor 31 is grown after a growth inhibitor film 15 is removed, as compared with the III-nitride semiconductor stacked structure of FIG. 6. As such, a region 15a in an m-plane substrate 10 where a seed layer 20 is not formed can serve as a growth inhibitor region. As the region 15a is free of the seed layer 20, the III-nitride semiconductor layer 31 does not grow therein. As a result, the III-nitride semiconductor layer 31 grows from the seed layer 20, as in FIG. 6. In other words, the III-nitride semiconductor 31a propagated along the c-axis direction from the window 16a forms a cavity 13 with the III-nitride semiconductor 31b propagated along the a-axis direction from the neighboring window 16b by growing over the region 15a. Since the growth inhibitor film 15 is removed prior to the growth of the III-nitride semiconductor layer 31, the III-nitride semiconductor layer 31 can grow without facing any problem even when polycrystals are produced during the formation of the seed layer 20 on the growth inhibitor film 15.

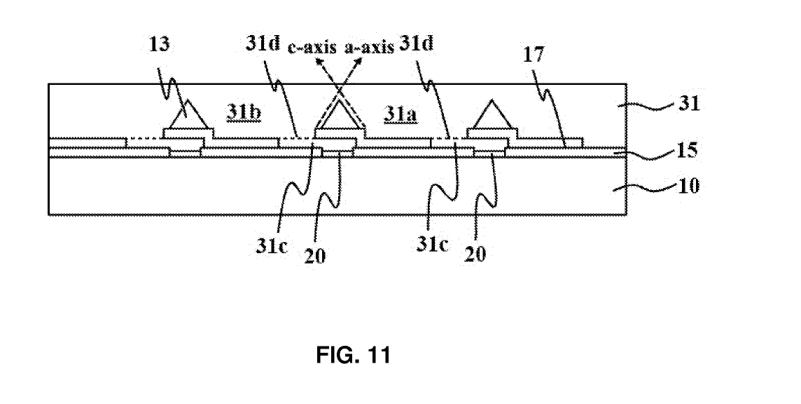

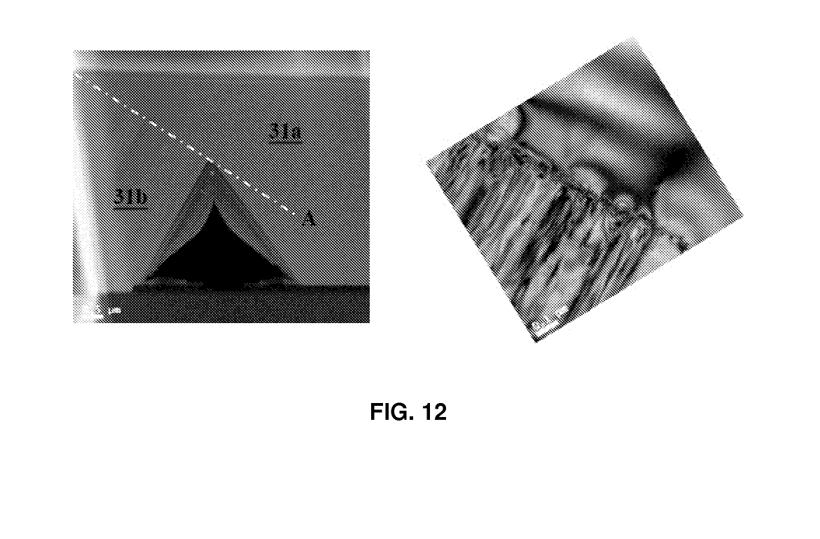

FIG. 11 is a diagrammatic view illustrating yet another example of a III-nitride semiconductor stacked structure according to the present disclosure, in which the III-nitride semiconductor stacked structure includes an additional growth inhibitor film 17 having a cavity 13 thereon. The cavity 13 is formed by interrupting the growth of a III-nitride semiconductor 31c on a seed layer 20, forming an additional growth inhibitor film 17 such that a plane 31d of the III-nitride semiconductor 31c propagated along the c-axis direction is exposed, and then growing a III-nitride semiconductor 31a and a III-nitride semiconductor 31b from the plane 31d, 31d. As mentioned above, and will be described below, the region where the III-nitride semiconductor 31c is propagated along the c-axis direction over the growth inhibitor film 15 is nearly free of defects (see FIG. 12) such that a III-nitride semiconductor layer 31 formed thereon can have substantially reduced defects.

FIG. 12 shows sectional images of the III-nitride semiconductor stacked structure of FIG. 6, which has grown in the structure illustrated in FIG. 8, in which the image on the right-hand side is an STEM (Scanning Transmission Electronic Microscope) image, and the image on the left-hand side is a TEM (Transmission Electronic Microscope) image. As can be seen from the STEM image, with respect to a coalescence plane A, those defects propagated from a III-nitride semiconductor 31b are blocked by a III-nitride semiconductor 31a, while a III-nitride semiconductor 31a, i.e. a III-nitride semiconductor propagated or grown along the c-axis direction, is nearly free of crystal defects. These features can be used advantageously in the growth of the Ill-nitride semiconductor stacked structure shown in FIG. 11. Blocking of the defects can be seen more clearly from the TEM image.

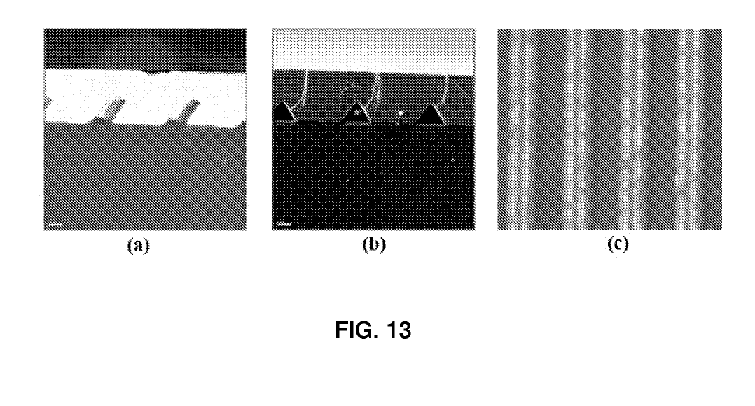

FIG. 13 shows sectional images of the III-nitride semiconductor stacked structure of FIG. 6, which has grown in the structure illustrated in FIG. 8, in which (a) is a CL (Cathodoluminescence) image, (b) is an SEM (Scanning Electron Microscope) image, and (c) is an optical microscope image. In the CL image, defects correspond to trenches formed in an obliquely upward right direction, which are kept from being propagated any further. The SEM image shows a cavity which is formed across the substrate. One thing that looks like a defect on the upper right side of the cavity is a flaw produced while cross cutting. In the optical microscope image, a brighter side corresponds to a cavity, and a clear surface thereof makes it possible to see inside the III-nitride semiconductor layer.

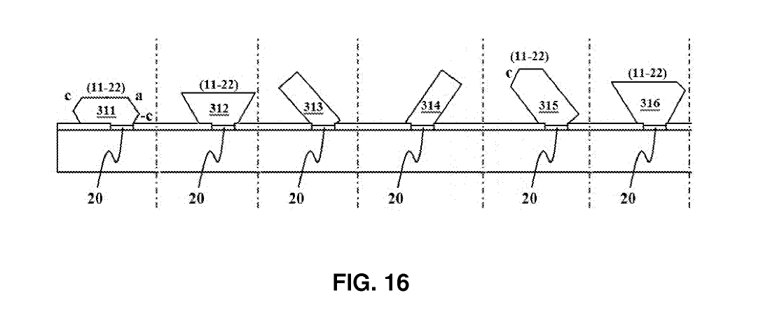

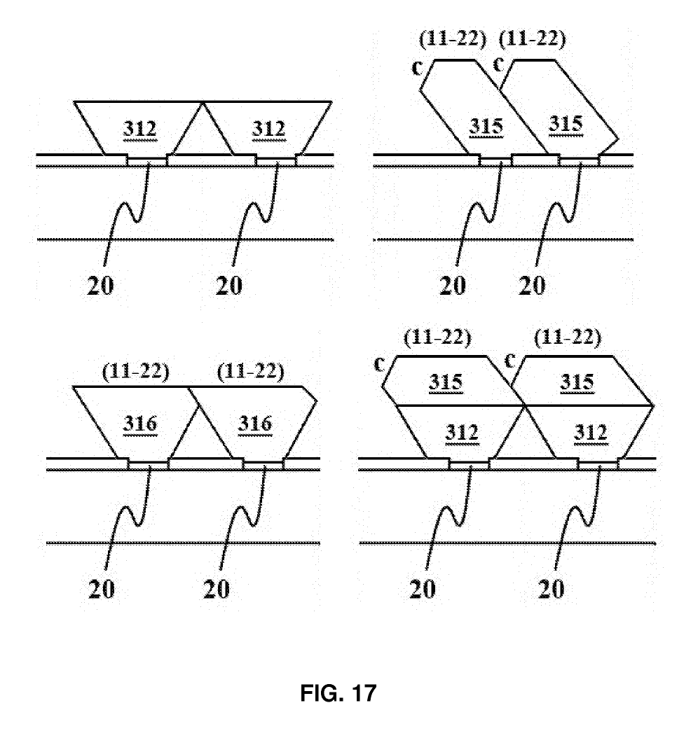

FIG. 16 and FIG. 17 are diagrammatic views describing an example of a method of growing a III-nitride semiconductor according to the present disclosure. In reference to a III-nitride semiconductor 311, a III-nitride semiconductor 312 can grow along the a- and c-plane directions at similar growth rates, given that these growth rates are relatively faster than the growth rates along the (11-22) plane directions. A III-nitride semiconductor 313 can grow at varied growth rates that are modified in the order of (11-22) plane direction>c-plane direction>a-plane direction. A III-nitride semiconductor 314 can grow at varied growth rates that are modified in the order of (11-22) plane direction>a-plane direction>c-plane direction. A III-nitride semiconductor 315 can grow at varied growth rates that are modified in the order of c-plane direction>(11-22) plane direction>a-plane direction, given that the growth rate along the c-plane direction being slightly faster than the growth rate along the (11-22) plane direction. A III-nitride semiconductor 316 can grow at varied growth rates that are modified in the order of c-plane direction>a-plane direction>(11-22) plane direction, given that the growth rate along the c-plane direction being slightly faster than the growth rate along the a-plane direction. FIG. 17 illustrates a coalescence process of easily planarizable III-nitride semiconductors, i.e. a III-nitride semiconductor 312, a III-nitride semiconductor 315 and a III-nitride semiconductor 316, each having a (11-22) plane. The III-nitride semiconductor 315 retains a c-plane even after the coalescence process. Accordingly, the III-nitride semiconductor 312 and the III-nitride semiconductor 316 can be planarized to a low height. Moreover, it is possible to block a region n by forming the III-nitride semiconductor 312 before growing the III-nitride semiconductor 315, namely, by making the region n illustrated in FIG. 7 narrower than the region m and then blocking the region n.

FIG. 15 is a view illustrating yet another example of the process of forming an electrical connection according to the present disclosure. Here, prior to bonding, a second semiconductor layer 50 and an active layer 40 are removed and thus a mesa surface 32 is formed on a first semiconductor layer 30 in the plurality of semiconductor layers 30, 40 and 50. Once the mesa surface 32 is formed, an isolation process can also be done on the plurality of semiconductor layers 30, 40 and 50 in advance. With this configuration, after the formation of the mesa surface 32, the active layer 40 may have a protective layer (e.g. SiO₂; it becomes a part of an insulating layer 110), which in turn would enhance the reliability of the device in the subsequence processes.

Moreover, in the III-nitride semiconductor stacked structure according to the present disclosure, a III-nitride semiconductor having excellent crystallinity can be grown on the m-plane substrate.

In this disclosure, it should be understood that the present disclosure is made up of individual technical ideals including the formation of a seed layer, the formation of sub III-nitride semiconductor bulks, the formation of III-nitride semiconductors, the coalescence of III-nitride semiconductors, the formation of a cavity, the method of reducing crystal defects, and the planarization method at low heights. That is, a skilled person in the art would understand that if someone obtains a seed layer using a different method from those described in this disclosure, other technical ideas according to this disclosure can be incorporated into that seed layer, individually and/or in combination. From this perspective, the present disclosure is related to the following:

(1) A method of forming a seed layer on an m-plane substrate provided with a growth inhibitor film, and a III-nitride semiconductor staked structure including the seed layer.

(2) A coalescence or planarization method of III-nitride semiconductor layers on an m-plane substrate provided with a growth inhibitor film, and a III-nitride semiconductor stacked structure obtained using the method.

(3) A method of growing a III-nitride semiconductor with reduced crystal defects on an m-plane substrate provided with a growth inhibitor film, and a III-nitride semiconductor stacked structure obtained using the method.

(4) A method of growing a III-nitride semiconductor having a cavity on an m-plane substrate provided with a growth inhibitor film, a III-nitride semiconductor staked structure, in particular, a configuration without an excessive thickness towards the planarization or the formation of a cavity and/or a configuration with reduced crystal defects despite the presence of a cavity, obtained using the method.

(5) A combination of the method and stacked structure.

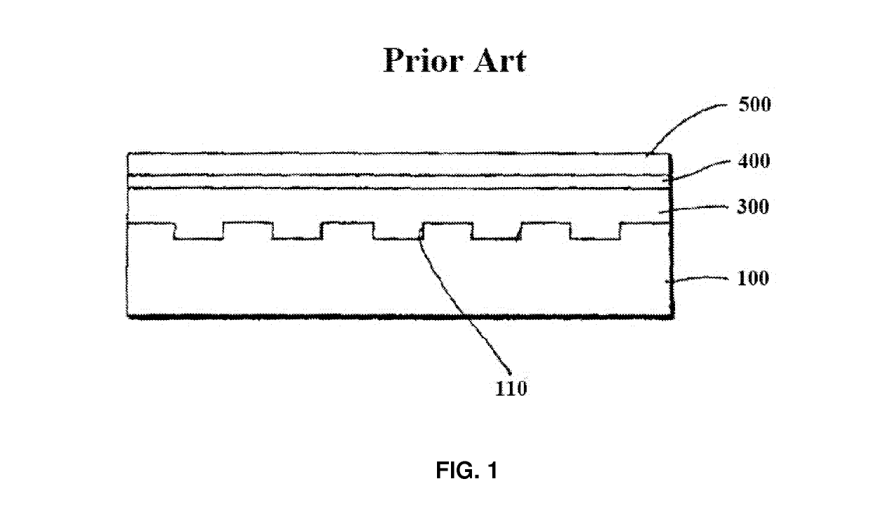

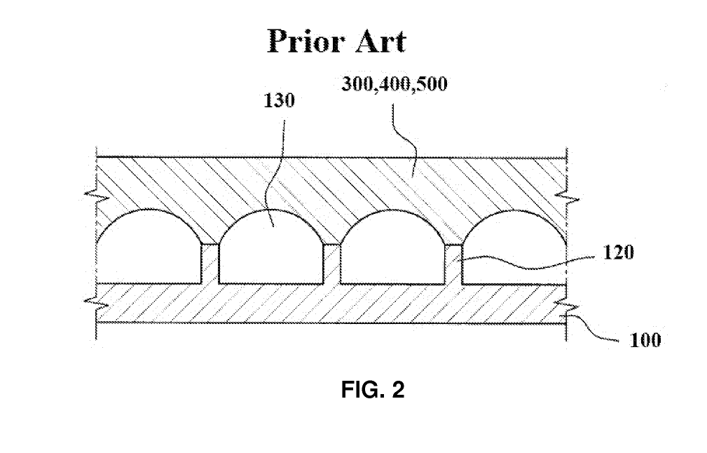

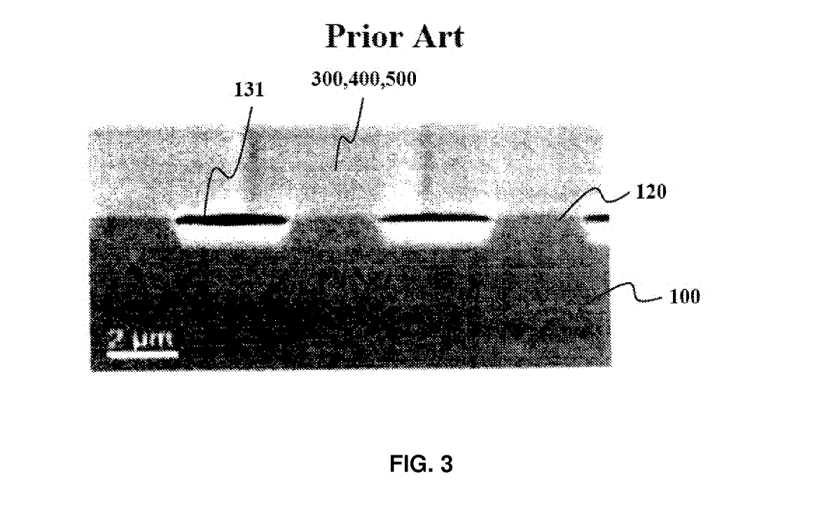

(6) A device, in particular, a semiconductor device using a PN junction (e.g. vertical LEDs, the semiconductor devices described in the Background Art in reference to FIG. 1 to FIG. 4) obtained using the method, the stacked structure, or the combination thereof.

1. A III-nitride semiconductor stacked structure comprising:
an m-plane substrate;
a growth inhibitor region located on the m-plane substrate, the growth inhibitor region having a plurality of windows for growing a III-nitride semiconductor;
a seed layer formed at least at regions corresponding to the plurality of windows on the m-plane substrate; and
a III-nitride semiconductor layer grown from the seed layer and coalesced after propagated along a-axis and c-axis directions, in which a III-nitride semiconductor propagated along the c-axis direction from one window and then propagated above the growth inhibitor region forms a cavity with a III-nitride semiconductor propagated along the a-axis direction from a neighboring window.

2. The III-nitride semiconductor stacked structure according to claim 1, wherein a growth inhibitor film is provided in the growth inhibitor region.

3. The III-nitride semiconductor stacked structure according to claim 2, wherein the seed layer is disposed between the growth inhibitor region and the m-plane substrate.

4. The III-nitride semiconductor stacked structure according to claim 1, wherein the growth inhibitor region is a region on the m-plane substrate where no seed layer is formed.

5. The III-nitride semiconductor stacked structure according to claim 1, wherein the structure further comprises an additional growth inhibitor film disposed on the plurality of windows, and the cavity is formed on the additional growth inhibitor film.

6. The III-nitride semiconductor stacked structure according to claim 1, wherein an a-plane of the III-nitride semiconductor propagated along the a-axis direction is reduced toward coalescence.

7. The III-nitride semiconductor stacked structure according to claim 1, wherein defects of the III-nitride semiconductor propagated along the a-axis direction are blocked by the III-nitride semiconductor propagated along the c-axis direction.

8. The III-nitride semiconductor stacked structure according to claim 1, wherein a c-plane of the III-nitride semiconductor propagated along the c-axis direction is reduced toward coalescence.

9. The III-nitride semiconductor stacked structure according to claim 6, wherein a c-plane of the III-nitride semiconductor propagated along the c-axis direction is reduced toward coalescence.

10. The III-nitride semiconductor stacked structure according to claim 7, wherein a c-plane of the III-nitride semiconductor propagated along the c-axis direction is reduced toward coalescence.

11. The III-nitride semiconductor stacked structure according to claim 1, wherein the III-nitride semiconductor to be grown at one window and the III-nitride semiconductor to be grown at a neighboring window have sub III-nitride semiconductor bulks, respectively, grown and propagated above the growth inhibitor region, as the lateral growth-propagation rate of the III-nitride semiconductor propagated along the c-axis direction is faster than that of the III-nitride semiconductor propagated along the a-axis direction.

12. The III-nitride semiconductor stacked structure according to claim 1, wherein the m-plane substrate is comprised of sapphire.

13. The III-nitride semiconductor stacked structure according to claim 9, wherein, after coalescence, defects of the III-nitride semiconductor propagated along the a-axis direction are blocked by the III-nitride semiconductor propagated along the c-axis direction.
